(19) United States
(12) Patent Application Publication
(10) Pub. No.: US 2026/0122818 A1
(43) Pub. Date: Apr. 30, 2026

(54) HANDLE MODULE AND RACK SYSTEM

(71) Applicant: Wiwynn Corporation, New Taipei City (TW)

(72) Inventors: Shang-Chien Li, New Taipei City (TW); Yun-Ting Chung, New Taipei City (TW)

(73) Assignee: Wiwynn Corporation, New Taipei City (TW)

(21) Appl. No.: 19/023,173

(22) Filed: Jan. 15, 2025

(30) Foreign Application Priority Data
Oct. 29, 2024 (TW) 113141195

(51) Int. Cl. H05K 7/14; H05K 7/20

(52) U.S. Cl. CPC H05K 7/1412; H05K 7/20636

(57) ABSTRACT

A handle module is configured to be disposed on a housing of an electronic device. The handle module includes a handle and a labor-saving assembly. The handle is rotatably disposed on the housing. The labor-saving assembly includes a first labor-saving component and a second labor-saving component. The first labor-saving component is disposed on the handle. The second labor-saving component is disposed on the housing and corresponds to the first labor-saving component. There is an attractive force between the first labor-saving component and the second labor-saving component. When the handle is moved from an open position to a closed position, the attractive force becomes larger.

### BACKGROUND OF THE INVENTION

### 1. Field of the Invention

The present disclosure relates to a handle module and a rack system, and more particularly, to a handle module which is favorable for installing an electronic device in a rack in a labor-saving manner and a rack system including the handle module.

### 2. Description of the Prior Art

With the vigorous development of cutting-edge technologies, such as the Internet of Things, edge computing and artificial intelligence, electronic devices with huge information processing capabilities, such as servers, are indispensable. Generally speaking, a plurality of electronic devices may be installed in a rack to improve the space utilization. In addition, there is a need to uninstall and reinstall the electronic devices after the electronic devices have been installed in the rack. For example, when the electronic devices are required to be maintained or repaired, the electronic devices are required to be uninstalled from the rack and taken out from rack. After the maintenance or repair is completed, the electronic devices are required to be reinstalled in the rack. When the methods for installing the electronic devices in the rack and/or uninstalling the electronic devices from the rack are unsatisfactory, work efficiency and operation safety may be affected. Therefore, how to improve the methods for installing the electronic devices in the rack and/or uninstalling the electronic devices from the rack is a goal in the related industries.

### SUMMARY OF THE INVENTION

According to one embodiment of the present disclosure, a handle module is configured to be disposed on a housing of an electronic device. The handle module includes a handle and a labor-saving assembly. The handle is rotatably disposed on the housing. The labor-saving assembly includes a first labor-saving component and a second labor-saving component. The first labor-saving component is disposed on the handle. The second labor-saving component is disposed on the housing and corresponds to the first labor-saving component. There is an attractive force between the first labor-saving component and the second labor-saving component. When the handle is moved from an open position to a closed position, the attractive force becomes larger.

According to another embodiment of the present disclosure, a rack system includes a rack, an electronic device and a handle module. The electronic device includes a housing. The handle module is disposed on the housing. The handle module includes a handle and a labor-saving assembly. The handle is rotatably disposed on the housing. The labor-saving assembly includes a first labor-saving component and a second labor-saving component. The first labor-saving component is disposed on the handle. The second labor-saving component is disposed on the housing and corresponds to the first labor-saving component. There is an attractive force between the first labor-saving component and the second labor-saving component. When the handle is moved from an open position to a closed position, the attractive force becomes larger. When the handle is at the closed position, the electronic device is installed in the rack.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an appearance of a rack system according to an embodiment of the present disclosure.

FIG. 2 is a schematic top view of the rack system shown in FIG. 1.

FIG. 3 is an enlarged view of a portion A shown in FIG. 2.

FIG. 4 is a schematic diagram of an appearance of the handle module shown in FIG. 2.

FIG. 5 is an exploded schematic diagram of the handle module shown in FIG. 4.

FIG. 6 is another schematic top view of the rack system shown in FIG. 1.

FIG. 7 is another schematic top view of the rack system shown in FIG. 1.

FIG. 8 is an enlarged view of a portion B shown in FIG. 7.

FIG. 9 is a schematic diagram showing a first liquid cooling connector to be connected with a second liquid cooling connector according to an embodiment of the present disclosure.

FIG. 10 is a diagram showing relationships between a spaced distance between the first liquid cooling connector and the second liquid cooling connector and an applied force according to an example of the present disclosure and a comparative example.

### DETAILED DESCRIPTION

In the following detailed description of the embodiments, reference is made to the accompanying drawings which form a part thereof, and shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purpose of illustration and is in no way limiting. In addition, identical numeral references or similar numeral references are used for identical elements or similar elements in the following embodiments.

Hereinafter, for the description of “the first feature is formed on or above the second feature”, it may refer to that “the first feature is in contact with the second feature directly”, or it may refer to that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first”, “second”, and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

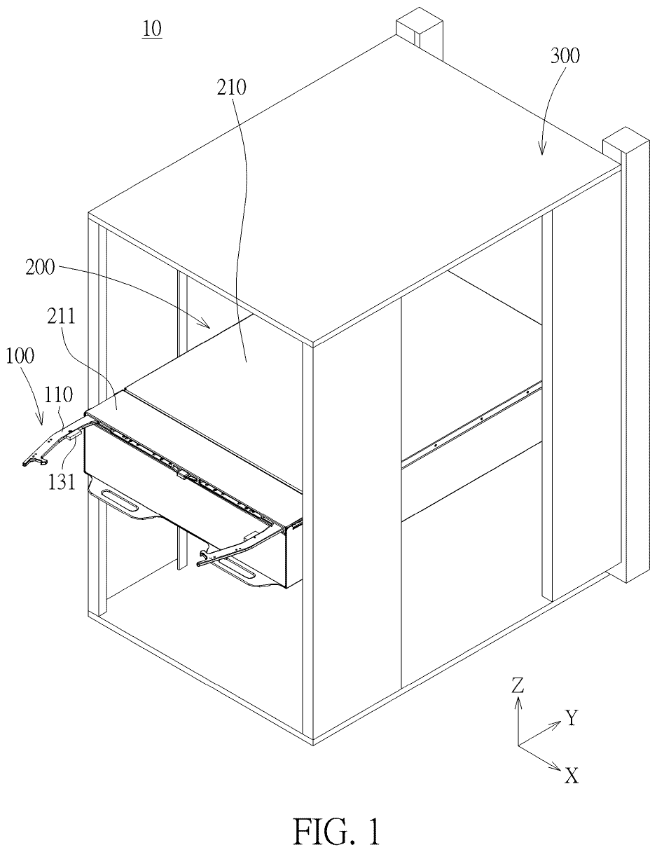

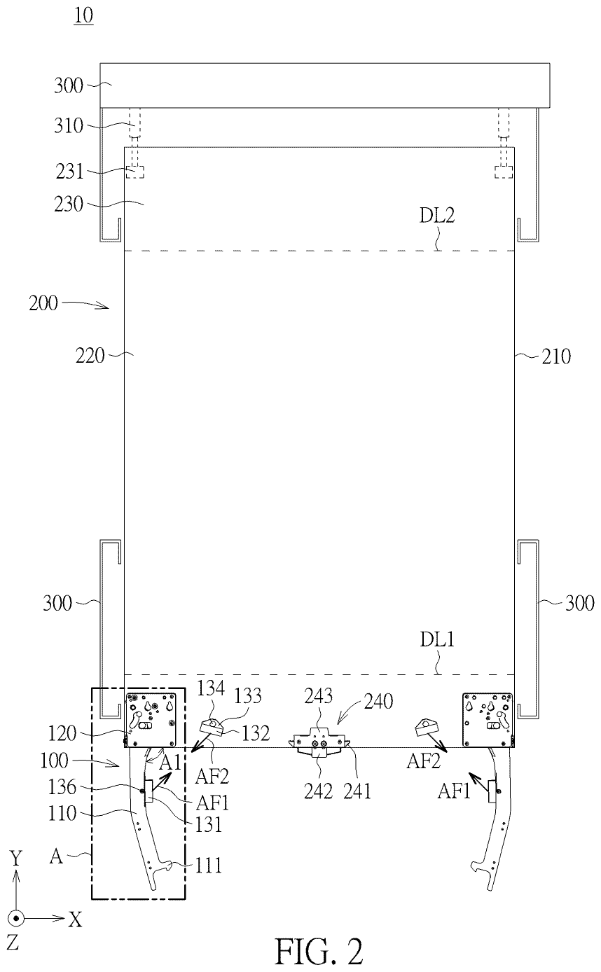

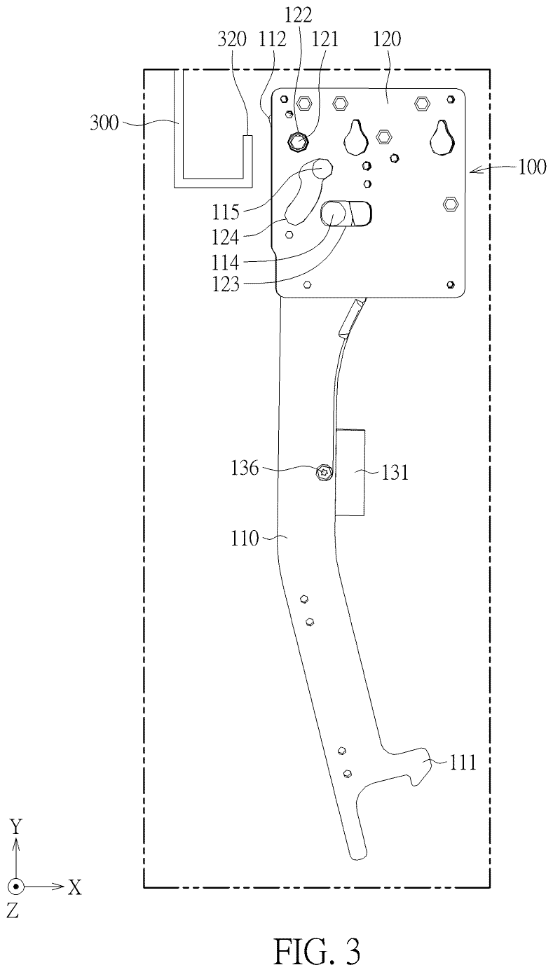

Referring to FIG. 1 to FIG. 3, FIG. 1 is a schematic diagram of an appearance of a rack system 10 according to an embodiment of the present disclosure, FIG. 2 is a schematic top view of the rack system 10 shown in FIG. 1, and FIG. 3 is an enlarged view of a portion A shown in FIG. 2. In FIG. 1 and FIG. 2, the electronic device 200 has not yet been installed in the rack 300. As shown in FIG. 1, the rack system 10 includes a rack 300, an electronic device 200 and a handle module 100. The electronic device 200 includes a housing 210, and the handle module 100 is disposed on the housing 210 of the electronic device 200. A user can install the electronic device 200 in the rack 300 with the assistance of the handle module 100. In FIG. 1, the rack 300 is installed with one electronic device 200, which is exemplary, and the present disclosure is not limited thereto. In some embodiments, the rack 300 may be installed with a plurality of electronic devices 200, and the plurality of electronic devices 200 may be arranged along a vertical direction (herein, the direction Z). In order to clearly show the portion of the handle module 100 that is shielded by the housing 210, the housing portion 211 shown in FIG. 1 is omitted in FIG. 2, and a boundary of the housing portion 211 is shown by a dashed line DL1.

As shown in FIG. 2, the electronic device 200 may further include a main device 220 and a cooling device 230 disposed in the housing 210. In FIG. 2, a dashed line DL2 shows a boundary between the main device 220 and the cooling device 230. As shown in FIG. 2, the main device 220 is disposed in the housing 210 and is disposed at a side of the housing 210 closer to the handle module 100 (herein, the front side), and the cooling device 230 is disposed in the housing 210 and is disposed at a side of the housing 210 away from the handle module 100 (herein, the rear side). The cooling device 230 is configured to cool the main device 220. The main device 220 may be, for example, a server, but not limited thereto. The cooling device 230 may be, for example, a liquid cooling device, a fan or a heat sink, but not limited thereto. In this embodiment, the cooling device 230 is exemplarily a liquid cooling device. The cooling device 230 includes a first liquid cooling connector 231, and the rack 300 includes a second liquid cooling connector 310 corresponding to the first liquid cooling connector 231. The first liquid cooling connector 231 is configured to be connected with the second liquid cooling connector 310 to exchange cooling liquid. During the guide stroke for connecting the first liquid cooling connector 231 and the second liquid cooling connector 310, a resistance is generated between the first liquid cooling connector 231 and the second liquid cooling connector 310, and the resistance pushes the main device 220 to move outside of the rack 300.

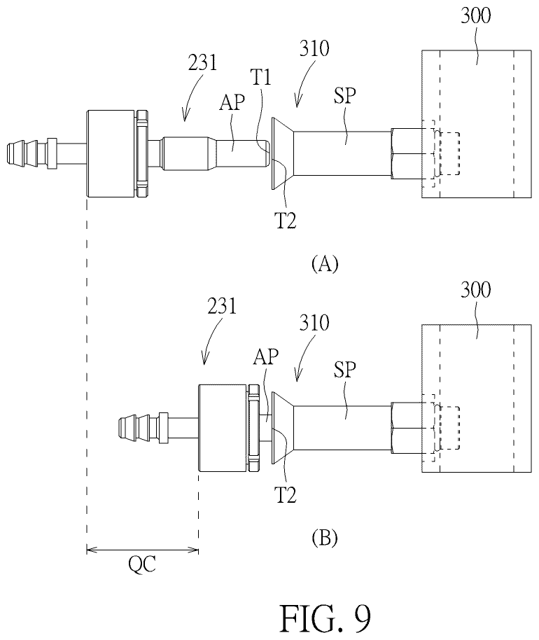

Referring to FIG. 9, which is a schematic diagram showing the first liquid cooling connector 231 to be connected with the second liquid cooling connector 310 according to an embodiment of the present disclosure. For the sake of conciseness, only the first liquid cooling connector 231, the second liquid cooling connector 310 and a portion of the rack 300 are shown in FIG. 9, and other components are omitted. As shown in FIG. 9, the first liquid cooling connector 231 may include an axial tube portion AP, and the second liquid cooling connector 310 may include a sleeve portion SP. When the first liquid cooling connector 231 is moved to align an end T1 of the axial tube portion AP with an end T2 of the sleeve portion SP, as shown in the part (A) of FIG. 9, the connection between the first liquid cooling connector 231 and the second liquid cooling connector 310 is started. When the first liquid cooling connector 231 continues to be moved to insert the axial tube portion AP into the sleeve portion SP and to be positioned at the sleeve portion SP, as shown in the part (B) of FIG. 9, the connection between the first liquid cooling connector 231 and the second liquid cooling connector 310 is completed. The aforementioned “guide stroke” may refer to the displacement distance QC of the axial tube portion AP from the start of the connection to the completion of the connection. According to an embodiment of the present disclosure, the guide stroke (i.e., the displacement distance QC) of the connection between the first liquid cooling connector 231 and the second liquid cooling connector 310 may be 40 millimeters (mm).

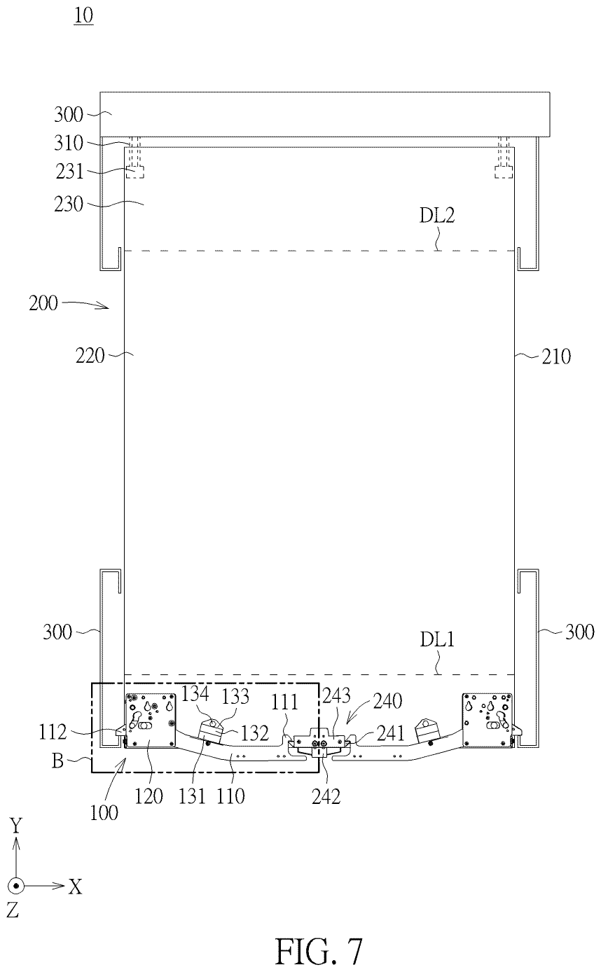

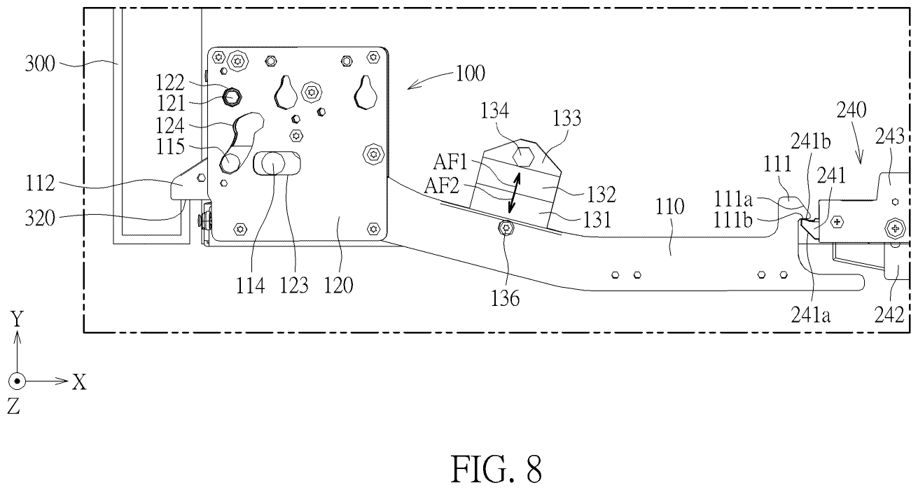

Reference is made to FIG. 2 again. The handle module 100 includes a handle 110 and a labor-saving assembly (not labeled). The labor-saving assembly includes a first labor-saving component 131 and a second labor-saving component 132. The first labor-saving component 131 is disposed on the handle 110. The second labor-saving component 132 is disposed on the housing 210 and corresponds to the first labor-saving component 131. There are attractive forces AF1 and AF2 between the first labor-saving component 131 and the second labor-saving component 132, wherein the attractive force AF1 is applied on the first labor-saving component 131, and the attractive force AF2 is applied on the second labor-saving component 132. When the handle 110 is moved from an open position (the position shown in FIG. 2) to a closed position (the position shown in FIG. 7 and FIG. 8), the attractive forces AF1 and AF2 become larger. Thereby, the attractive forces AF1 and AF2 between the first labor-saving component 131 and the second labor-saving component 132 may serve as assisting forces for installing the electronic device 200 in the rack 300, and the resistance, i.e., the friction force and the resistance generated between the first liquid cooling connector 231 and the second liquid cooling connector 310 generated from installing the electronic device 200 in the rack 300 can be reduced, which facilitates installing the electronic device 200 in the rack 300 in a labor-saving manner.

Specifically, in FIG. 2, the handle 110 is at the open position. At this stage, the connection between the first liquid cooling connector 231 and the second liquid cooling connector 310 has not yet been started or is about to be started (see the part (A) of FIG. 9). There is an included angle A1 between the handle 110 and the housing 210, and the included angle A1 may be less than or equal to 90 degrees. According to an embodiment of the present disclosure, when the handle 110 is at the open position, the included angle A1 may be 60 degrees to 80 degrees, such as 70 degrees. As shown in FIG. 3, when the handle 110 is at the open position, the abutted portion 320 of the rack 300 and the abutting portion 112 of the handle 110 do not abut against each other.

The first labor-saving component 131 is fixedly disposed on a surface (not labeled) of the handle 110 facing the housing 210, and the second labor-saving component 132 is rotatably disposed on the housing 210. Herein, the second labor-saving component 132 is rotatably disposed on an inner surface of the housing portion 211 (see FIG. 1). Specifically, the handle module 100 may further include a carrier 133 and a fixed shaft 134. The second labor-saving component 132 is fixedly connected with the carrier 133. A material of the carrier 133 may be, for example, a metal or a plastic, which is beneficial for processing or shaping. The fixed shaft 134 may be configured to connect the carrier 133 and the housing 210. The fixed shaft 134 may also serve as the pivot axis for the carrier 133 to rotate relative to the housing 210. The second labor-saving component 132 can rotate relative to the housing 210 through the carrier 133 and the fixed shaft 134.

The handle module 100 may further include another carrier (not shown) and a fastener 136. The first labor-saving component 131 is fixedly connected with the another carrier, and the another carrier may be embedded in an accommodation space (not shown) of the handle 110. The fastener 136 may be configured to fixedly connect the other carrier and the handle 110. However, the present disclosure is not limited thereto. In some embodiments, the first labor-saving component 131 may be directly embedded in the accommodation space of the handle 110 and may partially protrude or not protrude from the surface of the handle 110 facing the housing 210. Alternatively, the first labor-saving component 131 may be fixed on the handle 110 through an adhesive.

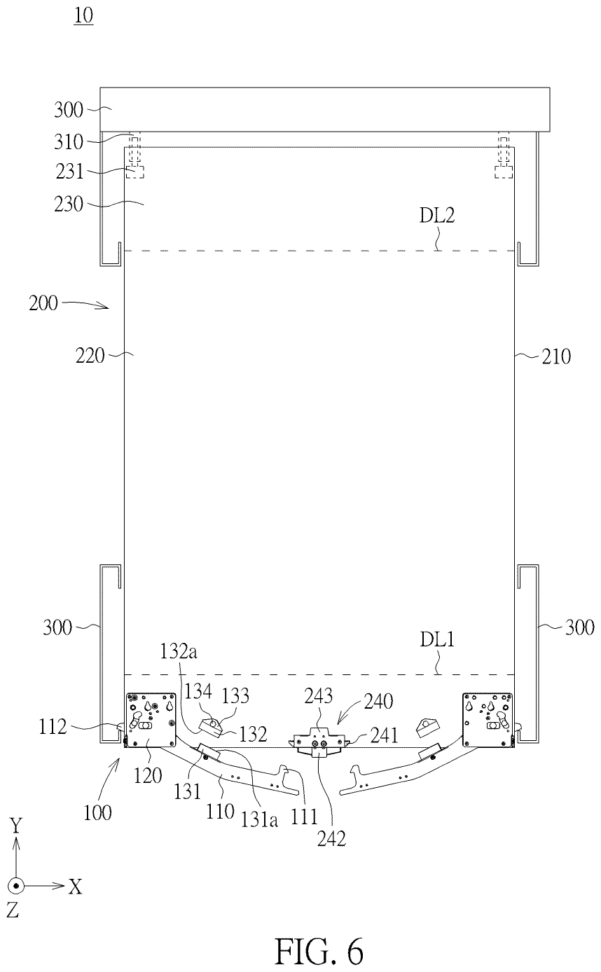

The first labor-saving component 131 and the second labor-saving component 132 may be magnetic components, such as magnets or coils. In this case, the attractive forces AF1 and AF2 are magnetic forces, and the magnetic pole of the first labor-saving component 131 facing the second labor-saving component 132 is different from the magnetic pole of the second labor-saving component 132 facing the first labor-saving component 131, so that the first labor-saving component 131 and the second labor-saving component 132 may attract each other. With the second labor-saving component 132 being rotatably disposed on the housing 210, the second labor-saving component 132 may be driven to rotate under the influence of the first labor-saving component 131 when the first labor-saving component 131 is driven to rotate relative to the housing 210 by rotating the handle 110 relative to the housing 210. Accordingly, the magnitudes of the attractive forces AF1 and AF2 between the second labor-saving component 132 and the first labor-saving component 131 can be maintained. For this part, references may be made to the relevant description of FIG. 6.

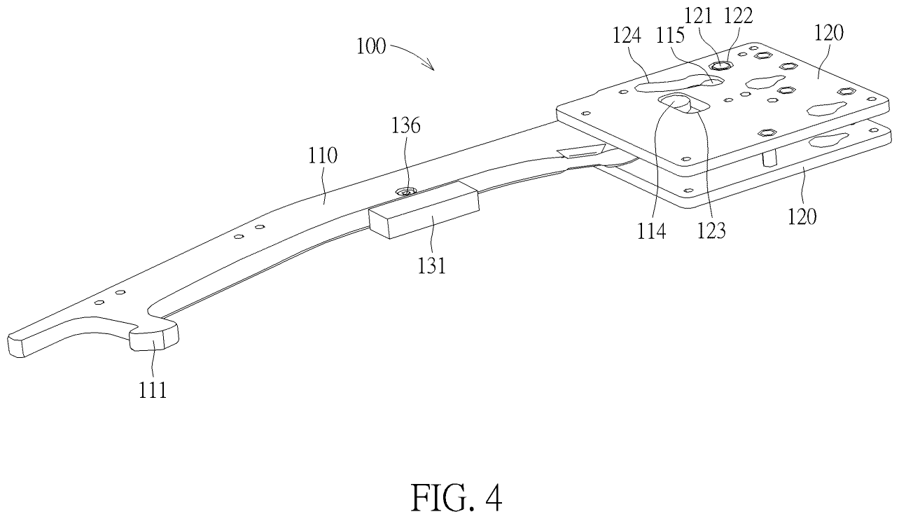

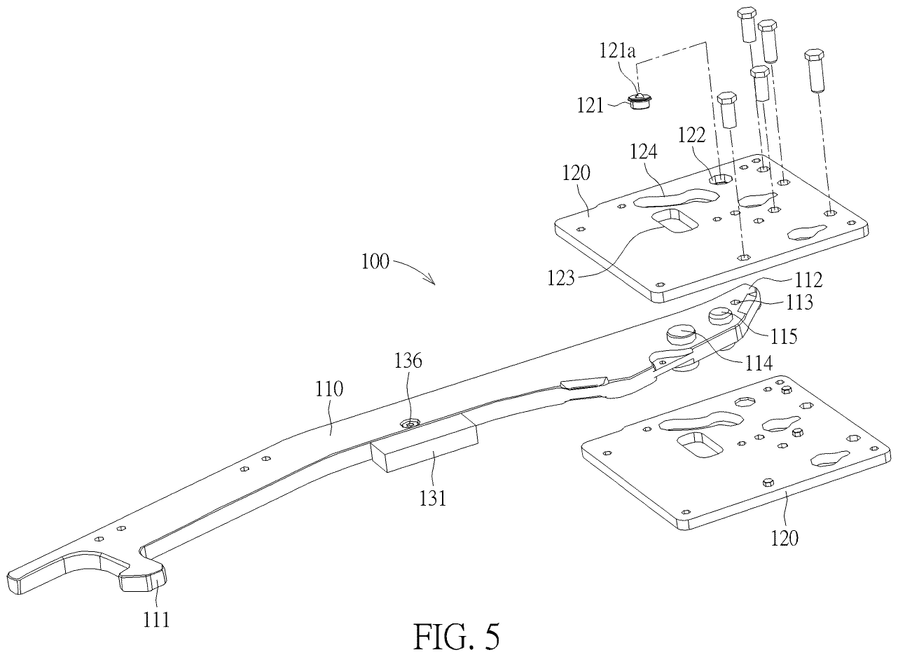

Referring to FIG. 2, FIG. 3, FIG. 4 and FIG. 5 at the same time, FIG. 4 is a schematic diagram of an appearance of the handle module 100 shown in FIG. 2, and FIG. 5 is an exploded schematic diagram of the handle module 100 shown in FIG. 4. The handle module 100 further includes a plate member 120 fixedly disposed on the housing 210, wherein the handle 110 is pivotably and movably disposed on the plate member 120.

In this embodiment, the plate member 120 includes a first sliding rail 123 and a second sliding rail 124. The handle 110 includes a first guide post 114 and a second guide post 115. The first guide post 114 and the second guide post 115 are respectively pivotably and movably disposed in the first sliding rail 123 and the second sliding rail 124. The first guide post 114 may serve as a driving shaft to drive the plate member 120 to displace, and the second guide post 115 may serve as a guiding shaft to guide the handle 110 to rotate. Thereby, the handle module 100 is a twin-shaft handle module, but not limited thereto. In other embodiments, the handle module 100 may be configured as a single-shaft handle module. In this embodiment, the first guide post 114 and the second guide post 115 are cylindrical posts and integrally formed on the handle 110, but not limited thereto. In some embodiments, the first guide post 114 and the second guide post 115 may be screws, studs or steel posts, and may be fixed on the handle 110 by fastening.

The number of the plate members 120 in the same handle module 100 is two, which are respectively disposed above and below the handle 110. The handle 110 includes two first guide posts 114 respectively disposed on the upper surface and the lower surface of the handle 110 corresponding to the plate members 120. Moreover, the handle 110 includes two second guide posts 115 respectively disposed on the upper surface and the lower surface of the handle 110 corresponding to the plate members 120. However, the present disclosure is not limited thereto. In other embodiments, the numbers of the plate members 120, the first guide posts 114 and the second guide posts 115 may be adjusted according to actual needs. In FIG. 2 and FIG. 3, when the handle 110 is at the open position, the first guide post 114 is at the first position in the first sliding rail 123, and the second guide post 115 is at the first position in the second sliding rail 124.

The handle 110 may include a first positioning portion 113 (see FIG. 5), and the first positioning portion 113 is exemplarily a recess formed on the surface of the handle 110. The plate member 120 may include a second positioning portion 121 and a hole 122, The second positioning portion 121 is disposed in the hole 122, and a protrusion 121a is formed on the surface of the second positioning portion 121 facing the handle 110. When the handle 110 is at the open position, the protrusion 121a of the second positioning portion 121 may be correspondingly embedded in the first positioning portion 113, so that the first positioning portion 113 and the second positioning portion 121 are engaged with each other. In other words, in this embodiment, the first positioning portion 113 has a concave structure, the second positioning portion 121 has a convex structure, and the first positioning portion 113 and the second positioning portion 121 are engaged with each other through the cooperation of the concave structure and the convex structure. In other embodiments, the structures of the first positioning portion 113 and the second positioning portion 121 may be reversed. That is, the first positioning portion 113 has a convex structure, and the second positioning portion 121 has a concave structure. In addition, in this embodiment, the second positioning portion 121 is an independent component that is separable from the plate member 120, but not limited thereto. In some embodiments, the second positioning portion 121 may be integrally formed on the surface of the handle 110. With the engagement between the first positioning portion 113 and the second positioning portion 121, the handle 110 can be prevented from freely swinging when the handle 110 is at the open position. Thereby, the operation safety can be improved.

Referring to FIG. 7 and FIG. 8, FIG. 7 is another schematic top view of the rack system 10 shown in FIG. 1, in which the electronic device 200 has been installed in the rack 300, and FIG. 8 is an enlarged view of a portion B shown in FIG. 7. In FIG. 7, the handle 110 is at the closed position. At this stage, the connection between the first liquid cooling connector 231 and the second liquid cooling connector 310 is completed (see the part (B) of FIG. 9). As shown in FIG. 8, when the handle 110 is at the closed position, one end of the handle 110 is locked with the housing 210, and the other end of the handle 110 abuts against the rack 300. Herein, the abutting portion 112 of the handle 110 abuts against the abutted portion 320 of the rack 300, and the first labor-saving member 131 and the second labor-saving member 132 contact each other.

Specifically, there are attractive forces AF1 and AF2 between the first labor-saving component 131 and the second labor-saving component 132. When the handle 110 is at the closed position, the first labor-saving component 131 and the second labor-saving component 132 are attracted to contact each other due to the attractive forces AF1 and AF2.

The electronic device 200 may further include an engaging member 240. The engaging member 240 includes an engaging portion 241, a release button 242 and a fixed seat 243. The fixed seat 243 is fixedly disposed on the housing 210, and the engaging portion 241 is telescopically disposed in the fixed seat 243. Herein, the engaging portion 241 may be telescopically disposed in the fixed seat 243 along a transverse direction (i.e., parallel to the direction X), and the engaging portion 241 includes a guide surface 241a and a stop surface 241b. The release button 242 can drive the engaging portion 241 to stretch or retract. When the release button 242 is pressed, the engaging portion 241 retracts into the fixed seat 243. When the press on the release button 242 is released, the engaging portion 241 stretches out from the fixed seat 243, as the state shown in FIG. 8. How to drive the engaging portion 241 to stretch or retract through the release button 242 is well known to those skilled in the art and is omitted herein.

The handle 110 may further include a hook portion 111, which is disposed at one end of the handle 110. The hook portion 111 includes a pushing surface 111a and an abutting surface 111b. When the handle 110 is about to enter the closed position, the pushing surface 111a of the hook portion 111 contacts and pushes against the guide surface 241a of the engaging portion 241, so that the engaging portion 241 retracts into the fixed seat 243. When the pushing surface 111a leaves the guide surface 241a, the engaging portion 241 return to stretch out from the fixed seat 243. The stop surface 241b of the engaging portion 241 and the abutting surface 111b of the hook portion 111 abut against each other, so that the hook portion 111 can be prevented from moving away from the housing 210, so as to prevent the handle 110 from ejecting out. In other words, when the handle 110 is at the closed position, the handle 110 may be locked with the housing 210 through the engaging member 240. When the lock state of the handle 110 is required to be released, the release button 242 can be pressed to drive the engaging portion 241 to retract into the fixed seat 243. Without the stopping of the stop surface 241b, the hook portion 111 can freely move away from the housing 210.

In other embodiments, the engaging member 240 of the electronic device 200 may be omitted. Due to the attractive forces AF1 and AF2 between the first labor-saving component 131 and the second labor-saving component 132, when the handle 110 is at the closed position, the first labor-saving component 131 and the second labor-saving component 132 attract and contact each other, which also can prevent the handle 110 from ejecting out.

Referring to FIG. 6, which is another schematic top view of the rack system 10 shown in FIG. 1, in which the electronic device 200 has not yet been installed in the rack 300. In FIG. 6, the handle 110 is at an intermediate position between the open position (see FIG. 2) and the closed position (see FIG. 7). For example, the handle 110 may be in the process of moving from the open position to the closed position, or the handle 110 may be in the process of moving from the closed position to the open position. At this stage, the first guide post 114 may be located between the first position (see FIG. 3) and the second position (see FIG. 8) or at the second position in the first sliding rail 123, and the second guide post 115 is located between the first position (see FIG. 3) and the second position (see FIG. 8) in the second sliding rail 124.

Specifically, when FIG. 6 is the process of the handle 110 moving from the open position to the closed position, the first liquid cooling connector 231 and the second liquid cooling connector 310 may be in the process of connecting, and the electronic device 200 is pushed outwardly (that is, the electronic device 200 is pushed outwardly along the direction Y) by the resistance between the first liquid cooling connector 231 and the second liquid cooling connector 310. Meanwhile, the second labor-saving component 132 disposed on the housing 210 can provide the first labor-saving component 131 disposed on the handle 110 the inward attraction force AF1 (see FIG. 2), which is beneficial to offset the resistance, and the electronic device 200 can be installed in the rack 300 in a labor-saving manner.

In addition, the first labor-saving component 131 has a first surface 131a, and the second labor-saving component 132 has a second surface 132a facing the first surface 131a. Compared with the second surface 132a not directly opposite to the first surface 131a, when the second surface 132a is directly opposite to the first surface 131a, the attractive forces AF1 and AF2 (see FIG. 2) between the second labor-saving component 132 and the first labor-saving component 131 are larger. The aforementioned “the second surface 132a being directly opposite to the first surface 131a” may refer to that the second surface 132a is parallel to the first surface 131a, and the second surface 132a partially overlaps or completely overlaps the first surface 131a in a direction perpendicular to the first surface 131a or the second surface 132a.

It should be noted that when the handle 110 rotates relative to the housing 210, the orientation of the first surface 131a changes continuously. With the second labor-saving component 132 being rotatably disposed on the housing 210, it is beneficial for the second labor-saving component 132 to rotate under the influence of the first labor-saving component 131. Accordingly, it is beneficial to keep the second surface 132a directly opposite to the first surface 131a. That is, it is beneficial to keep the first surface 131a and the second surface 132a parallel to each other and is beneficial to maintain the magnitudes of the attractive forces AF1 and AF2 (see FIG. 2) between the second labor-saving component 132 and the first labor-saving component 131. For example, when the first labor-saving component 131 and the second labor-saving component 132 are magnetic components, the magnitudes of the magnetic poles of the first labor-saving component 131 and the second labor-saving component 132 may be adjusted, so that the first surface 131a and the second surface 132a may keep parallel to each other when an included angle A1 between the handle 110 and the housing 210 is within a predetermined angle. According to an embodiment of the present disclosure, the predetermined angle may be, for example, 60 degrees to 0 degree.

When FIG. 6 is the process of the handle 110 moving from the closed position to the open position, the first liquid cooling connector 231 and the second liquid cooling connector 310 may be in the process of disconnecting, and the electronic device 200 is pushed outwardly (that is, the electronic device 200 is pushed outwardly along the direction Y) by the resistance between the first liquid cooling connector 231 and the second liquid cooling connector 310, and the handle 110 is driven to eject outwardly. When the ejecting speed of the handle 110 is excessively fast, the equipment and the worker around the rack system 10 may be hit by the handle 110, so as to affect the operation safety.

In order to solve the problem that the ejecting speed of the handle 110 is excessively fast, the conventional handle module is further equipped with a spring, in which one end of the spring is fixed to the plate member 120 and the other end of the spring is fixed to the handle 110. With the force provided by the spring to bring the handle 110 to move toward the housing 210, the ejecting speed of the handle 110 can be reduced. However, when the handle 110 is getting closer to the open position, the deformation of the spring increases, and the elastic force increases correspondingly. The excessive elastic force may disengage the engagement between the first positioning portion 113 and the second positioning portion 121, which results in the handle 110 swinging freely when the handle 110 is at the open position. In the present disclosure, with the second labor-saving component 132 providing the first labor-saving component 131 the inward attractive force AF1, the ejecting speed of the handle 110 can be reduced. Accordingly, the operation safety can be improved, and the engagement between the first positioning portion 113 and the second positioning portion are not affected easily.

According to the above description, when the electronic device 200 has not yet been installed in the rack 300 and the handle 110 is at the open position (as shown in FIG. 2), and when the electronic device 200 is required to be installed in the rack 300, the user can firstly hold the handle 110, and push the handle 110 to allow the electronic device 200 to move toward the inside of the rack 300, so that the first liquid cooling connector 231 and the second liquid cooling connector 310 are started to connect with each other. With the labor-saving assembly, when the electronic device 200 is driven to start the guide stroke for connecting the first liquid cooling connector 231 and the second liquid cooling connector 310 by the handle module 100, the labor-saving effect can be improved significantly. When the connection between the first liquid cooling connector 231 and the second liquid cooling connector 310 is completed, the electronic device 200 is installed in the rack 300. In other words, when the electronic device 200 is installed in the rack 300, the first liquid cooling connector 231 and the second liquid cooling connector 310 are fixedly connected with each other. The aforementioned “fixedly connected with each other” may refer to that there is no relative movement between the first liquid cooling connector 231 and the second liquid cooling connector 310.

When the electronic device 200 is required to be uninstalled from the rack 300 due to the need of maintenance, repair, etc., the user can press the release button 242, so that the handle 110 is no longer locked with the housing 210. Next, the user can hold the handle 110 and pull the handle 110 to allow the electronic device 200 to move outwardly from the rack 300. In other words, when the handle 110 leaves the closed position, the electronic device 200 is uninstalled from the rack 300. With the labor-saving assembly, the handle 110 can be prevented from ejecting out quickly when the handle 110 is no longer locked with the housing 210.

In this embodiment, the number of handle modules 100 is two. During operation, the user can hold the two handles 110 with both hands to install the electronic device 200 in the rack 300 or uninstall the electronic device 200 from the rack 300. However, the present disclosure is not limited thereto. In some embodiments, the number of the handle module 100 may be one. During operation, the user may hold the handle 110 with one hand and hold a side of the electronic device 200 opposite to the handle 110 with the other hand. The single handle module 100 can also achieve the effect of saving labor and slowing down the ejecting speed of the handle 110. In this embodiment, the cooling device 230 is exemplarily a liquid cooling device, but not limited thereto. When the cooling device 230 is a non-liquid cooling device, the handle module 100 can also achieve the effect of saving labor and slowing down the ejecting speed of the handle 110. In this embodiment, the number of the first labor-saving component 131 and the second labor-saving component 132 in the same handle module 100 is one, but not limited thereto. The numbers of the first labor-saving component 131 and the second labor-saving component 132 can be adjusted according to actual needs. When the same handle module 100 includes a plurality of first labor-saving components 131 and a plurality of second labor-saving components 132, the numbers of the first labor-saving components 131 and the second labor-saving components 132 may be the same, the plurality of first labor-saving components 131 may be spaced apart from each other on the handle 110, and the plurality of second labor-saving components 132 may be spaced apart from each other on the housing 210 and correspond to the plurality of first labor-saving components 131.

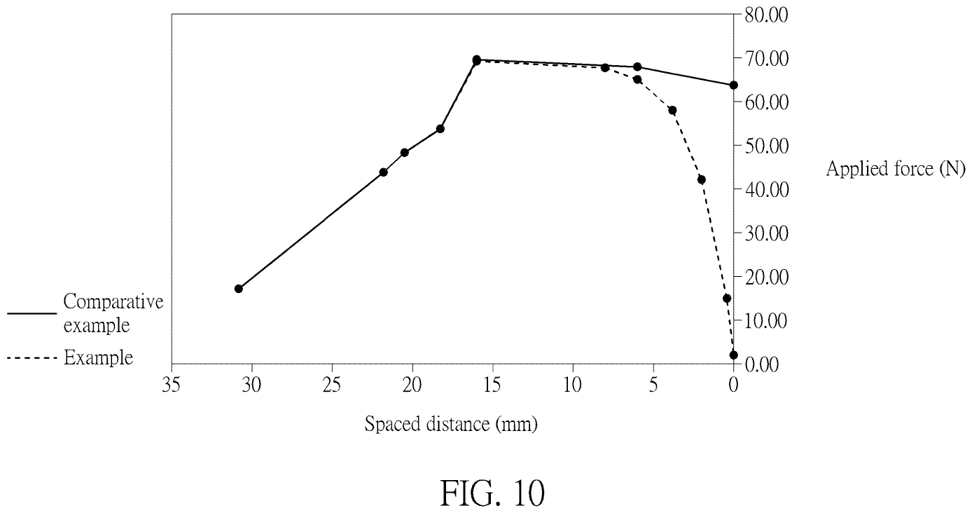

Referring to FIG. 10, which is a diagram showing relationships between a spaced distance between the first liquid cooling connector and the second liquid cooling connector and an applied force according to an example of the present disclosure and a comparative example. Specifically, a handle module according to an example of the present disclosure and a handle module according to a comparative example are respectively used to install an electronic device in a rack. During the guide stroke for connecting the first liquid cooling connector and the second liquid cooling connector, the applied forces provided by one hand of a worker at different spaced distances between the first liquid cooling connector and the second liquid cooling connector are measured. The difference between the handle module of the example and the handle module of the comparative example is that the handle module according to the comparative example not disposed with a labor-saving assembly. As shown in FIG. 10, when the guide stroke for connecting the first liquid-cooled connector and the second liquid-cooled connector is started, the applied force increases gradually when the spaced distance is shortened. When the spaced distance is close to 15 mm, the applied force reaches the maximum value, which is about 70 newtons (N). When the handle module of the comparative example is used, at the end of the guide stroke, such as at the stage with the spaced distance of 15 mm to 0 mm, the applied force only decreases slightly, while the applied force required at the end of the guide stroke decreases significantly by using the handle module according to the present disclosure.

Compared with the prior art, in the present disclosure, with disposing a labor-saving assembly on the handle module, attractive forces can be provided between the first labor-saving component and the second labor-saving component. When the handle module is applied to install an electronic device in a rack, it is beneficial to reduce the applied force required to install the electronic device in the rack. Furthermore, when the electronic device is uninstalled from the rack, it can prevent the handle from ejecting out at a high speed, so as to improve the operation safety.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A handle module configured to be disposed on a housing of an electronic device, the handle module comprising:
a handle rotatably disposed on the housing; and
a labor-saving assembly, comprising:
a first labor-saving component disposed on the handle; and
a second labor-saving component disposed on the housing and corresponding to the first labor-saving component, wherein there is an attractive force between the first labor-saving component and the second labor-saving component, and when the handle is moved from an open position to a closed position, the attractive force becomes larger.

2. The handle module of claim 1, wherein when the handle is at the closed position, the first labor-saving component and the second labor-saving component contact each other.

3. The handle module of claim 1, wherein the attractive force is a magnetic force.

4. The handle module of claim 1, wherein the first labor-saving component is fixed on a surface of the handle facing the housing.

5. The handle module of claim 1, wherein the second labor-saving component is rotatably disposed on the housing.

6. The handle module of claim 1, wherein the first labor-saving component has a first surface, the second labor-saving component has a second surface facing the first surface, and when an included angle between the handle and the housing is within a predetermined angle, the first surface and the second surface keep parallel to each other.

7. The handle module of claim 1, wherein when the handle is at the closed position, the handle is locked with the housing.

8. The handle module of claim 1, further comprising:
a plate member fixedly disposed on the housing, wherein the handle is pivotably and movably disposed on the plate member.

9. The handle module of claim 8, wherein the handle comprises a first positioning portion, the plate member comprises a second positioning portion, and when the handle is at the open position, the first positioning portion and the second positioning portion are engaged with each other.

10. The handle module of claim 9, wherein one of the first positioning portion and the second positioning portion has a convex structure, and another one of the first positioning portion and the second positioning portion has a concave structure.

11. A rack system, comprising:
a rack;
an electronic device comprising a housing; and
a handle module disposed on the housing, wherein the handle module comprises:
a handle rotatably disposed on the housing; and
a labor-saving assembly comprising a first labor-saving component and a second labor-saving component, wherein the first labor-saving component is disposed on the handle, the second labor-saving component is disposed on the housing and corresponds to the first labor-saving component, there is an attractive force between the first labor-saving component and the second labor-saving component, when the handle is moved from an open position to a closed position, the attractive force becomes larger, and when the handle is at the closed position, the electronic device is installed in the rack.

12. The rack system of claim 11, wherein the electronic device further comprises:
a main device disposed in the housing; and
a liquid cooling device configured to cool the main device.

13. The rack system of claim 12, wherein the liquid cooling device comprises a first liquid cooling connector, the rack comprises a second liquid cooling connector, and when the electronic device is installed in the rack, the first liquid cooling connector is fixedly connected with the second liquid cooling connector.

14. The rack system of claim 11, wherein when the handle leaves the closed position, the electronic device is uninstalled from the rack.

15. The rack system of claim 11, wherein when the handle is at the closed position, one end of the handle is locked with the housing, and another end of the handle abuts against the rack.

16. The rack system of claim 11, wherein the attractive force is a magnetic force.

17. The rack system of claim 11, wherein the first labor-saving component is fixedly disposed on a surface of the handle facing the housing, and the second labor-saving component is rotatably disposed on the housing.

18. The rack system of claim 11, further comprising:
a plate member fixedly disposed on the housing, wherein the handle is pivotably and movably disposed on the plate member.

19. The rack system of claim 11, wherein the handle comprises a first positioning portion, the plate member comprises a second positioning portion, and when the handle is at the open position, the first positioning portion and the second positioning portion are engaged with each other.

20. The rack system of claim 19, wherein one of the first positioning portion and the second positioning portion has a convex structure, and another one of the first positioning portion and the second positioning portion has a concave structure.
